(19) United States
(12) Patent Application Publication
(10) Pub. No.: US 2001/0051431 A1
(43) Pub. Date: Dec. 13, 2001

(54) FABRICATION PROCESS FOR DISHING-FREE CU DAMASCENE STRUCTURES

(76) Inventors: SAKET CHADDA, COLORADO SPRINGS, CO (US); JACOB D. HASKELL, PALO ALTO, CA (US); GARY A. FRAZIER, COLORADO SPRINGS, CO (US); JAMES D. MERRITT, COLORADO SPRINGS, CO (US)

Correspondence Address: THOMAS SCHNECK, POST OFFICE BOX 2-E, SAN JOSE, CA, 951090005

(21) Appl. No.: 09/352,545

(22) Filed: Jul. 12, 1999

(51) Int. Cl. H01L 21/302; H01L 21/461

(52) U.S. Cl. 438/690

(57) ABSTRACT

Fabrication of copper damascene interconnects includes depositing an oxide layer atop an underlying conductive layer such as a substrate or a metal layer, which is then patterned and etched. A barrier layer having an optional copper seed layer is then deposited atop the patterned oxide layer. The barrier layer is patterned and etched to remove some of the barrier material. Copper is plated atop the barrier layer. CMP polishing is performed to bring the copper layer to the level of the barrier layer. Polishing is continued to further polish down the barrier layer and any remaining copper to the level of the oxide layer. The result is a dishing-free copper damascene structure.

### TECHNICAL FIELD OF THE INVENTION

The present invention relates generally to semiconductor manufacturing processes and in particular to a planarization method for copper damascene structures.

### BACKGROUND ART

Copper is the metal of choice for interconnect films in today's high density semiconductor devices. Copper exhibits lower sheet resistance as compared to aluminum and gold. However, removal of copper from unwanted areas is accomplished chiefly through the use of chemical mechanical planarization (CMP) processing since practical dry-etching techniques are not available. In a typical CMP operation, a wafer is pressed against a polishing pad in the presence of a slurry. Under controlled pressure, velocity and temperature conditions, the wafer is moved relative to the polishing pad. Particles suspended in the slurry abrade the surface of the wafer by mechanical polishing and chemicals in the slurry oxidize and etch the surface, a form of chemical polishing, to remove material from the surface to achieve the desired planarization.

Referring to FIGS. 9-16, a prior art CMP process will be discussed showing how copper interconnects and contact pads of a semiconductor chip are formed. Examples of such structures are shown in the integrated circuit (IC) device 100 of FIG. 9. A portion of IC 100 is shown having copper traces 120 and 140 formed atop a substrate portion 102. Copper interconnects are typically used above at the second metal level and higher. Accordingly, the first metal level is not shown in order to clarify the explanation of the invention. A first end 122 of trace 120 includes a via 130 which provides electrical contact to the active area of a device formed in an underlying substrate, or to a trace formed in an underlying metal layer. The other end of trace 120 terminates in a copper pad 110, e.g. a bonding pad or a solder pad.

FIG. 10 is a side view of IC 100 as seen from view line 2-2 in FIG. 9. This view shows a substrate 102 having an insulative layer 206 formed thereon. Via 130 provides an electrical path from the first end 122 of trace 120 to an underlying structure 202. In the case of FIG. 2, the structure 202 is seen to be the active area of a device formed in the substrate.

The cross-sectional views of FIGS. 11-16, illustrate how the copper structures of FIGS. 9 and 10, such as trace 120 and pad 110, are typically formed. Beginning with FIG. 11, substrate 102 having active area 202 is provided with a nitride layer 402 and an oxide layer 404. Using conventional photolithographic etching techniques, portions of oxide layer 404′ and nitride layer 402′ shown in phantom are removed, FIG. 12. In FIG. 13, a barrier layer 406 of tantalum or a tantalum compound is deposited atop oxide 404 and exposed portions of nitride layer 402. FIG. 14 shows a layer of copper 408 plated atop barrier layer 406 by conventional electroplating methods. Next, the copper layer is polished by CMP to remove portions 408′ of the copper shown in phantom lines to the level of the underlying barrier layer, FIG. 15. CMP polishing continues in order to planarize the barrier layer 406 with respect to oxide layer 404, resulting in the final product shown in FIG. 16.

All currently available CMP slurries have a high selectivity against all known barrier metals relative to copper, typically in the range of 10:1-6:1.Thus, after the upper layer of copper is polished off (FIG. 15), continued polishing of the tantalum-based barrier layer 406 and the copper layer results in copper being removed at a higher rate than the barrier. This overpolishing to remove all of the barrier layer results in a dishing artifact 410 of the copper structures. Furthermore, due to bending of the polishing pad in the larger areas such as contact pads 110, the dishing effect is even more pronounced.

A common approach to minimize the dishing effect is to use two separate slurry systems, wherein a first slurry is used to polish the copper layer down to the barrier layer and a second slurry is used which polishes the barrier and the remaining copper layer at the same rate albeit a much slower rate. This approach reduces dishing for narrow copper structures such as interconnects, but does not eliminate dishing. For large area bond pads where dishing of more than 1000 Å can occur. More significantly, most polishing systems do not have two separate platens with two different slurry systems hooked up to each. In source systems which do have a dual platen and slurry arrangement, the need to have sequential polishing reduces throughput. Such systems are cumbersome and expensive to maintain, time consuming to use and still do not adequately avoid dishing in the case of large area structures such as bond pads.

What is needed is a cost-effective dishing-free copper damascene process. It is desirable to provide a dishing-free process that does not increase the complexity of the processing equipment. There is a need for a dishing-free process which does not significantly decrease production throughput. It is also desirable to provide a process that does not increase the maintenance requirement of the processing equipment.

### SUMMARY OF THE INVENTION

In accordance with the present invention, a dishing-free copper damascene process includes depositing an oxide layer atop a first surface of an integrated circuit device. Next the oxide layer is patterned and etched as needed forming a pattern of trenches which will constitute the interconnect pattern and vias which provide electrical contact to conductive portions of the underlying first surface. A barrier layer is deposited atop the oxide, including the trenches and vias formed in the oxide. It may be necessary to provide the barrier layer with a copper seed layer to improve the adhesion characteristics of the plated copper. Portions of the barrier layer are then removed. Copper is then electroplated atop the remaining portions of the barrier layer. Most of the remaining barrier material is found in the trenches and vias of the oxide layer. Consequently, the electroplating process will deposit most of the copper in those regions, making the copper initially higher in those regions. A CMP polishing is performed to planarize the copper, removing upper portions of the copper to the level of the barrier layer. Polishing continues until the barrier layer is planarized to the level of the oxide layer.

The result is a highly planarized copper damascene structure that is virtually free of dishing artifacts, even in the large-area structures such as bonding pads. Since the barrier layer is removed from most of the surface of the oxide layer prior to electroplating the copper, little overpolishing is needed to remove the barrier material from the oxide.

### BRIEF DESCRIPTION OF THE DRAWINGS

FIGS. 1-8 are isometric views of an integrated circuit during processing in accordance with the invention.

FIG. 9 is a perspective view of a typical prior art integrated circuit device.

FIG. 10 shows a cross-sectional view taken along view lines 2-2 in FIG. 9.

FIGS. 11-16 shows a typical prior art fabrication process for copper structures.

### BEST MODE FOR CARRYING OUT THE INVENTION

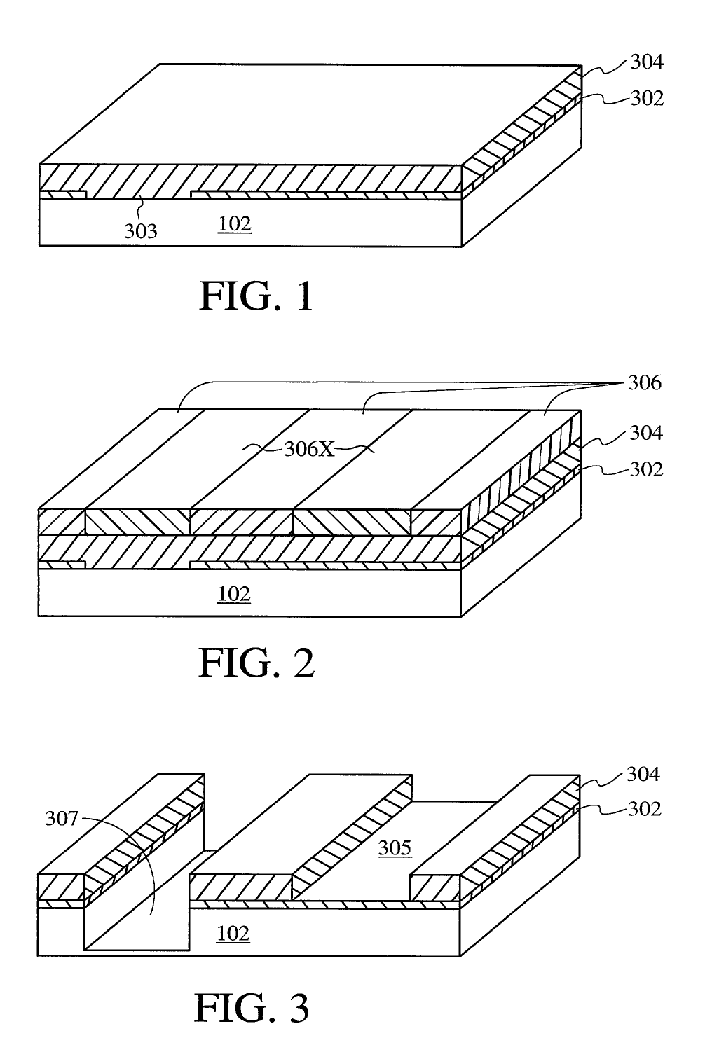

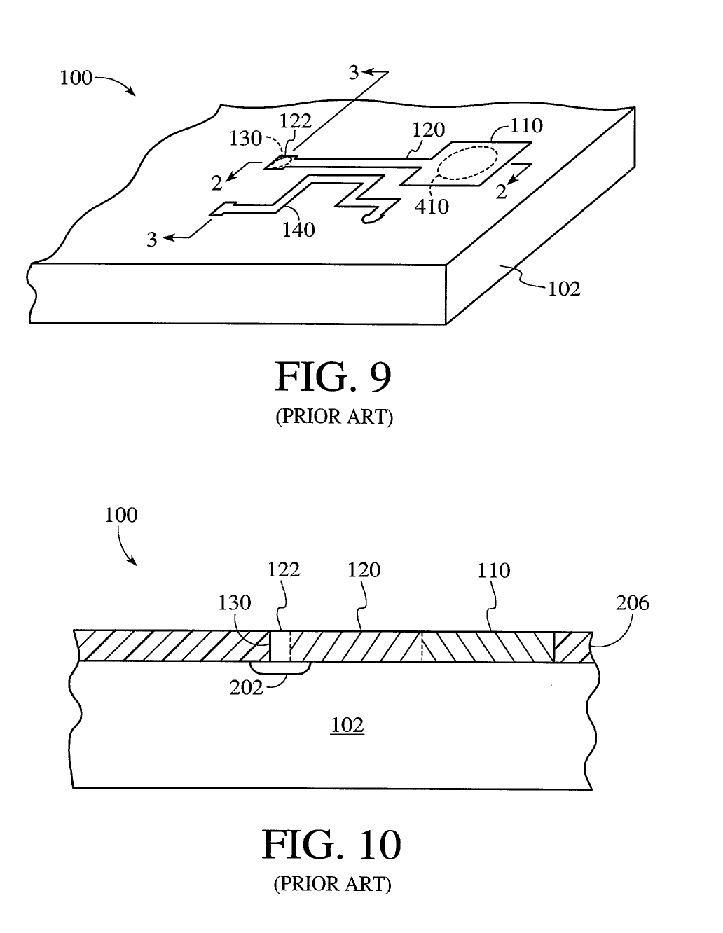

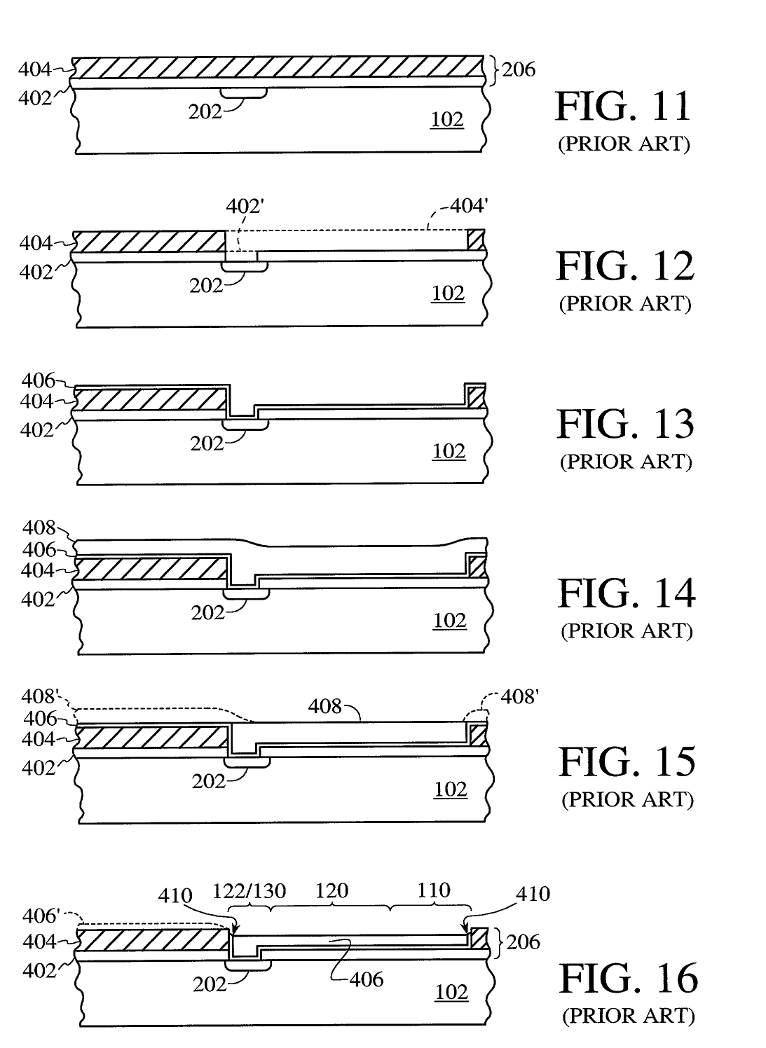

Copper damascene interconnects formed in accordance with the invention begin with conventional processing steps as discussed briefly above in connection with FIG. 1. In order to provide a more complete discussion of the preferred mode of the invention, a more detailed explanation will be provided in the context of the isometric views of FIGS. 1-8. In order to better appreciate the advantages of the invention, the isometric views are taken along view line 3-3 of FIG. 9 across traces 120 and 140.

FIG. 1 shows a substrate portion 102, typically an upper portion of a silicon wafer, which is understood to have a plurality of devices, typically transistors, formed therein by known fabrication methods. As an initial step in fabrication of a copper damascene metal interconnect layer, a silicon nitride layer 302, typically 250 Å-500 Å thick, is deposited atop the substrate surface. The nitride layer serves as a barrier to an oxide etch of the subsequent oxide layer 304 from reaching the silicon surface of the underlying substrate. Typically, the oxide layer is 5000 Å thick. A portion 303 of the nitride layer 302 was removed in a process prior to deposition of the oxide layer to accommodate a via.

Next as illustrated in FIG. 2, a conventional photolithographic technique is applied to pattern oxide layer 304 to produce vias to the underlying substrate 102 and to define the traces which will comprise the interconnects. This involves depositing a layer of photoresist 306, exposing it through a pattern, and removing the exposed resist 306x in a develop step.

In FIG. 3, the exposed oxide is removed during an oxide etch, stopping at the nitride layer 302 and thus exposing portion 305′ of the nitride layer. The channels created by the removal of the oxide will eventually become pads for traces 120 and 140 as well as via 130, as seen in FIG. 9. Where the nitride layer was removed, the channel 307 extends into the substrate portion 102 because both oxide and substrate material have been removed.

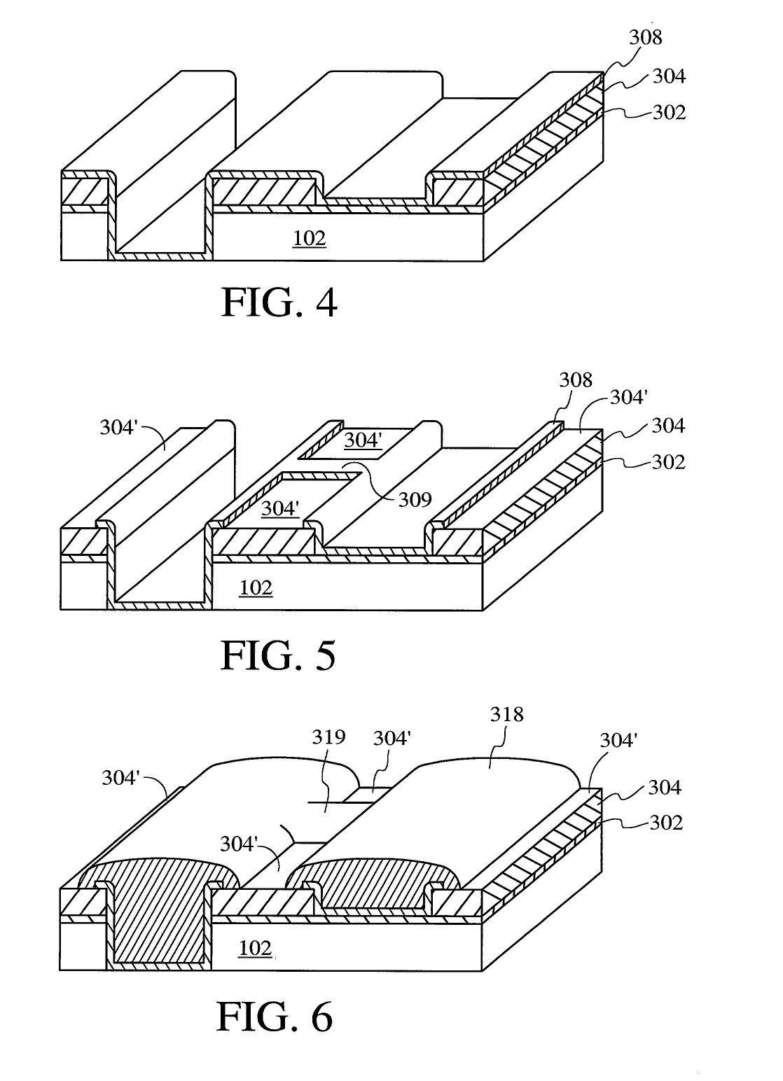

As shown in FIG. 4, a blanket coat of a barrier layer 308 next is deposited atop the remaining portions of oxide layer 304, upon the exposed portions of nitride layer 302 and into the exposed portion 307 of the substrate. The barrier layer 308 is typically a tantalum compound such as TaN or TaW. In addition, barrier layer 308 may include a copper seed layer. Whether the seed layer is provided depends on the uniformity and adhesion properties of the subsequently plated copper upon the barrier layer. If adhesion of plated copper is poor, a thin seed layer roughly 50-100 Å may be needed. The seed layer can be deposited via known physical vapor deposition (PVD) methods.

Next a second photolithographic step is performed, this time on barrier layer 308. In a manner similar to the etch step shown in FIG. 2, a photoresist is dispensed atop the barrier layer. The photoresist is then exposed through a mask and removed to expose portions of the barrier layer. The exposed portions of the barrier layer are then removed by known plasma anisotropic etch processing. Where barrier layer 308 is a composite of tantalum and copper, anisotropic etching might be problematic due to low vapor pressure of the byproducts when etching bulk copper films. However, since the copper portion of the barrier layer is only a thin copper seed layer, it can be simply ablated with physical bombardment of an inert gas in a plasma atmosphere. Following removal of the exposed portions of the barrier layer, the remaining photoresist is removed. The result is shown in FIG. 5 where it can be seen that much of barrier layer 308 has been removed to expose portions of the surface 304′ of oxide layer 304.

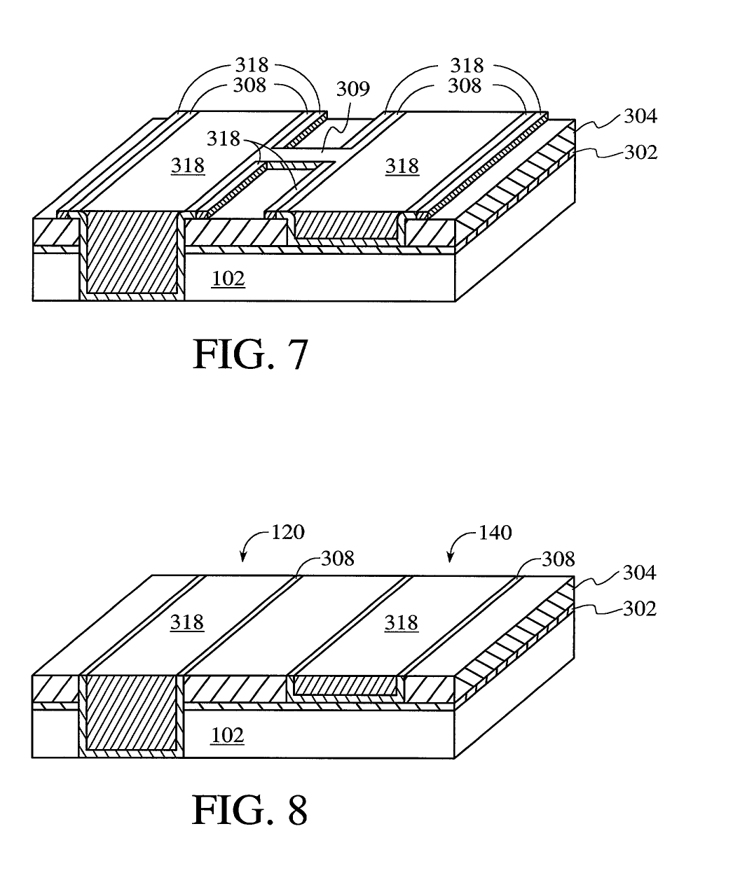

Next as shown in FIG. 6, copper layer 318 is selectively deposited atop the remaining portions of the barrier layer. This is accomplished by known electroplating processing methods. Finally, a CMP polishing step is performed to remove the copper layer 318 to the level of the barrier layer 308 as shown in FIG. 7. Only small strips of the barrier layer 308, 309 remain atop the oxide layer. Thus, continued polishing will easily remove these strips as well as planarizing the copper portions 318 to the level of the oxide layer. The final product shown in FIG. 8 exhibits a planarized copper structure and more importantly is free of dishing artifact.

Two key aspects of the invention are noted. First, there is the removal of substantially all of barrier layer 308 from the upper surface of the oxide layer. Compare FIG. 5 with FIG. 8. This is illustrated by the relatively large areas of exposed oxide surface 304′ where barrier material was removed. The advantage of doing this is shown in FIG. 7, where the CMP polish of copper layer 318 eventually reaches the level of barrier layer 308. There is much less barrier material to polish, so that both the copper and barrier material will subsequently polish down to the oxide level at roughly the same rate. There is no need to overpolish as in the case with prior art techniques. Consider, for example, FIG. 15 where the removed copper 408′ exposes a large area of barrier layer 406, keeping in mind that the copper structures occupy a relatively smaller area. Because of the large area, there is considerably more barrier material which requires considerably more polishing than does the copper material 406. Consequently, by the time the barrier material 406′ is sufficiently removed, dishing 410 will have occurred in the copper, as illustrated in FIG. 16.

The second key aspect of the invention is that not all of the barrier material is removed from the upper surface of the oxide layer. Referring again to FIG. 5, some of the barrier material 309 is preserved. These interconnecting traces 309 of barrier material ensure that all remaining unetched portions of barrier layer 308 are interconnected. This ensures electrical conductivity throughout the entire layer for the purposes of the subsequent electroplating of copper. Thus, the pattern used for etching the barrier layer must: (1) match the pattern of the used to etch the oxide layer (FIG. 2) and (2) must include the necessary interconnecting traces 309 to ensure electrical conductivity throughout the layer. One method of doing this is to form a composite pattern consisting of the pattern used to etch oxide layer 304 and the metal mask pattern of an adjacent metal layer, namely the previous metal level or the next metal level. Such a composite should work for most cases because alternate metal levels are usually orthogonal in order to minimize capacitance between metal levels. It is desirable to have resist coverage that is connected throughout the wafer. Alternatively, features can be added to the pattern used to etch oxide layer 304 to produce a mask for etching barrier layer 308 which guarantees electrical conductivity throughout remaining portions of the barrier layer.

Thus by removing some of the barrier material prior to plating the copper, overpolish is minimized and thus the process time of CMP is reduced. In addition, less copper is consumed because of the selective plating of copper and more significantly faster throughput is realized because copper electroplating time is reduced. While, the invention requires an additional photo and etch step to remove portions of barrier layer 308, time is saved through faster copper deposition and faster CMP polish, and in the end dishing-free copper damascene structures.

1. In a semiconductor device having a first layer of material, a method of forming copper structures comprising the steps of:
depositing a barrier layer atop a first surface of said first layer of material;
removing portions of said barrier layer to expose portions of said first surface;
depositing a layer of copper atop remaining portions of said barrier layer, whereby most of said copper is formed atop said remaining portions of said barrier layer; and
planarizing said layer of copper and portions of said barrier layer to the level of said first surface.

2. The method of claim 1 further including etching channels and vias through said first surface and into said first layer of material; wherein said step of depositing a barrier layer includes depositing said barrier layer within walls and bottom surfaces of said channels and vias; wherein said step of removing portions of said barrier layer includes removing said barrier layer from bottom surfaces of said vias.

3. The method of claim 1 wherein said barrier layer includes a copper seed layer.

4. The method of claim 1 wherein said remaining portions of said barrier layer are in electrical contact with each other.

5. The method of claim 4 wherein said step of depositing a layer of copper is a step of electroplating copper atop said remaining portions of said barrier layer.

6. The method of claim 1 wherein said step of planarizing is a CMP polishing step.

7. The method of claim 6 wherein said CMP polishing step is performed using a single type of slurry.

8. In a semiconductor device having a conductive layer, a method of forming copper damascene structures comprising the steps of:
depositing an oxide layer atop said conductive layer;
etching back portions of said oxide layer to expose portions of said conductive layer, including depositing a first photoresist layer atop said oxide layer and exposing said first photoresist layer with a first patterned mask;
depositing a barrier layer atop remaining portions of said oxide layer and atop exposed portions of said conductive layer;
etching back portions of said barrier layer to expose portions of said oxide layer, including depositing a second photoresist layer atop said barrier layer and exposing said second photoresist layer with a second patterned mask;
depositing a copper layer atop remaining portions of said barrier layer; and
removing portions of said copper layer and said barrier layer to the level of said oxide layer.

9. The method of claim 8 wherein said step of depositing an oxide layer includes first depositing a oxidation barrier layer, and said step of etching back portions of said oxide layer includes etching back portions of said oxidation barrier layer.

10. The method of claim 9 wherein said oxidation barrier layer is a nitride layer.

11. The method of claim 8 wherein said step of removing portions of said copper layer includes CMP polishing of said copper layer.

12. The method of claim 11 wherein said steps of removing portions of said copper layer and said barrier layer are performed using a single slurry.

13. The method of claim 8 wherein said step of etching back portions of said barrier layer includes maintaining electrical conductivity throughout said remaining portions of said barrier layer.

14. The method of claim 13 wherein said step of depositing a copper layer is a step of electroplating copper atop said remaining portions of said barrier layer.

15. The method of claim 8 wherein said step of depositing a barrier layer includes forming a copper seed layer.

16. The method of claim 8 wherein said step of depositing a barrier layer includes forming a layer of material selected from the group comprising: Ta, TaN, and TaW.

17. The method of claim 16 wherein said step of depositing a barrier layer further includes depositing a copper seed layer.
